(19) United States
(12) Patent Application Publication
(10) Pub. No.: US 2008/0007443 A1
(43) Pub. Date: Jan. 10, 2008

(54) Input interface circuit adapted to both of analog and digital signals

(75) Inventor: Hiroshi Inose, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 11/822,267

(22) Filed: Jul. 3, 2007

(30) Foreign Application Priority Data
Jul. 7, 2006 (JP) 2006-188106

(51) Int. Cl. H03M 1/34

(52) U.S. Cl. 341/158

(57) ABSTRACT

An input interface circuit is provided with: a reference voltage level generator generating a reference voltage level; a differential amplifier having a non-inverting input receiving an input signal and an inverting input receiving the reference voltage level; and a feedback circuit for achieving feedback of the output signal of the differential amplifier to the inverting input. The feedback circuit includes a switch for allowing and prohibiting the feedback of the output signal.

### BACKGROUND OF THE INVENTION

1. Field of the Invention

The present invention relates to an input interface circuit and a semiconductor IC (integrated circuit) incorporating the same.

2. Description of the Related Art

Recent advances in the digital signal processing technology provide broader applications for semiconductor ICs. Semiconductor ICs are incorporated in many electronic controllers within television sets, video recorders, automobiles, and so on. This is accompanied by the increase in the number of circuit elements integrated within controller ICs and signal processor ICs, and enhances the increase in the number of data input/output terminals of semiconductor ICs.

Controller ICs and signal processor ICs are often required to handle not only digital signals but also analog signals; such ICs are referred to as mixed analog-digital ICs. In a typical mixed analog-digital IC, analog input/output terminals are provided separately from digital input/output terminals. Such architecture, however, undesirably increases the total number of input/output terminals of a mixed analog-digital IC. This undesirably increases the chip size and manufacture cost of the mixed analog-digital IC.

One approach for reducing the number of input/output terminals of a mixed analog-digital IC is to use one input/output terminal for interfacing both of analog and digital signals, as disclosed in Japanese Laid-Open Patent Application Nos. JP-A Showa 64-58118 and JP-A 2004-222248. In the technology disclosed in these documents, analog and digital signals are interfaced by the same input/output terminal, while the analog and digital signals are handled by an analog circuit and a digital circuit, separately; the analog and digital circuits are selectively used.

The inventor has discovered, however, that the architecture in which analog and digital signals are separately handled by analog and digital circuits is not suitable for reducing the chip size and cost.

### SUMMARY

In one embodiment, an input interface circuit is provided with: a reference voltage level generator generating a reference voltage level; a differential amplifier having a non-inverting input receiving an input signal and an inverting input receiving the reference voltage level; and a feedback circuit for achieving feedback of the output signal of the differential amplifier to the inverting input. The feedback circuit includes a switch for allowing and prohibiting the feedback of the output signal. Such architecture effectively reduces the chip size and cost of the input interface circuit.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram illustrating the structure of an input interface circuit according to a first embodiment of the present invention;

FIG. 2 is a circuit diagram illustrating the structure of an input interface circuit according to a second embodiment of the present invention;

FIG. 3 is a circuit diagram illustrating the structure of an input interface circuit according to a third embodiment of the present invention; and

FIG. 4 is a circuit diagram illustrating the structure of an input interface circuit according to a fourth embodiment of the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

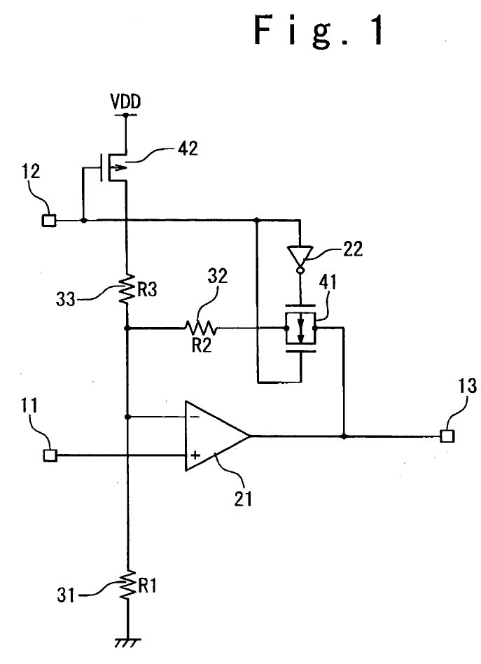

FIG. 1 is a circuit diagram illustrating the configuration of an input interface circuit according to a first embodiment of the present invention. The input interface circuit is provided with a differential amplifier 21, an inverter circuit 22, resistors 31, 32, 33, and MOS (metal oxide semiconductor) switches 41 and 42. The MOS switch 41 is composed of a transfer gate that includes PMOS and NMOS transistors having commonly-connected sources and drains, and the MOS switch 42 is composed of a PMOS transistor. In the following, the resistances of the resistors 31, 32, 33 are referred to as R1, R2, and R3, respectively. A signal input terminal 11 is connected with the non-inverting input (denoted by the symbol “+”) of the differential amplifier 21. The MOS switch 42 and the resistors 33 and 31 are serially connected between a first power line VDD of the power supply level Vdd and a second power line GND of the ground level. The control terminal of the MOS switch 42 is connected with an analog/digital select terminal 12. The connecting node of the resistors 33 and 31 is connected with the inverting input (denoted by the symbol “−”) of the differential amplifier 21, and also connected with one end of the resistor 32. An output terminal of the differential amplifier 21 is connected with a signal output terminal 13, and also connected with the other end of the resistor 32 through the MOS switch 41. One of the control terminals of the MOS switch 41 is directly connected with the analog/digital select terminal 12 and the other is connected with the same through the inverter circuit 22.

The inverter circuit 22 is used to drive the PMOS transistor of the MOS switch 41. The MOS switch 41 is turned on and off in response to the voltage level on the analog/digital select terminal 12. Specifically, the MOS switch 41 is turned on when the analog/digital select terminal 12 is pulled up to the “High” level (simply referred to as the “H” level, hereinafter), while being turned off when the analog/digital select terminal 12 is pulled down to the “Low” level (simply referred to as the “L” level, hereinafter).

The MOS switch 42 is turned on and off in response to the voltage level on the analog/digital select terminal 12. Specifically, the MOS switch 42 is turned off when the analog/digital select terminal 12 is pulled up to the “H” level, while being turned on when the analog/digital select terminal 12 is pulled down to the “L” level. The MOS switches 41 and 42 perform complementary operations; the MOS switch 42 is turned off when the MOS switch 41 is turned on, and vice versa.

In this configuration, the MOS switch 41 and the resistor 32 operate together as a feedback circuit when the analog-digital select terminal 12 is pulled up to the “H” level. The MOS switch 41 is electrically connected between the output terminal 13 and the non-inverting input of the differential amplifier 21 to function as a feedback resistor, when the analog-digital select terminal 12 is pulled up to the “H” level. This allows the differential amplifier 21 to operate as a positive-phase amplifier that provides in-phase amplification for the input signal fed to the signal input terminal 11. When the analog-digital select terminal 12 is pulled down to the “L” level, on the other hand, the negative feedback loop is cut off, and the differential amplifier 21 operates as a comparator that compares the voltage levels on the inverting and non-inverting inputs thereof. In this case, the resistors 33 and 31 functions as a reference voltage level generator which generates a reference voltage level through voltage division of the power supply level Vdd.

The signal input terminal 11 receives an analog input signal or a digital input signal, and the signal output terminal 13 outputs an analog output signal or a digital output signal, accordingly. For achieving analog amplification of the input signal fed to the signal input terminal 11, the analog-digital select terminal 12 is pulled up to the “H” level. For digitizing the signal fed to the signal input terminal 11, on the other hand, the analog-digital select terminal 12 is pulled down to the “L” level.

One advantage of the input interface circuit according to the first embodiment is that the gain of the analog amplification can be adjusted independently of the threshold level of the signal digitization of the input signal.

A description is first given of the analog amplification of the input signal fed to the signal input terminal 11. In this case, the analog-digital select terminal 12 is pulled up to the “H” level, and the MOS switch 42 is turned off, while the MOS switch 41 is turned on. As a result, the output of the differential amplifier 21 is connected with the inverting input of the differential amplifier 21 through the resistor 32, and also connected to ground through the resistor 31. This allows the input interface circuit to operate as a positive-phase amplifier.

For the case that the on-resistance of the MOS switch 41 is sufficiently smaller than the resistance R2 of the resistor 32 (this is usually the case in practice), the gain Ga of the positive-phase amplifier is as follow:

Ga=1+R2/R1. (1)

### Therefore, the gain Ga can be adjusted by the resistances R1 and R2 as desired.

For the signal digitalization of the input signal fed to the signal input terminal 11, on the other hand, the analog-digital select terminal 12 is pulled down to the “L” level. This results in that the MOS switch 42 is turned on, while the MOS switch 41 is turned off. In this case, the output signal of the differential amplifier 21 is not fed back, and the differential amplifier 21 operates as a comparator. Therefore, the signal level on the output of the differential amplifier 21 depends on the comparison result between the voltage levels on the inverting and non-inverting inputs. The inverting input of the differential amplifier 21 receives a reference voltage level Vth generated through voltage division of the power supply voltage Vdd by the resistors 33 and 31. The reference voltage level Vth is identical to the threshold level of the signal digitization of the input signal. When the signal level on the non-inverting input is higher than the reference voltage level Vth, the output of the differential amplifier 21 is pulled up to the “H” level. When the signal level on the non-inverting input is lower than the reference voltage level Vth, on the other hand, the output of the differential amplifier 21 is pulled down to the “L” level.

When the on-resistance of the MOS switch 41 is sufficiently smaller than the resistances R1 and R3 of the resistors 31 and 33 (this is usually the case in practice), the reference voltage level Vth, which is the threshold level of the signal digitization, is as follow:

Vth=Vdd×R1/(R1+R3). (2)

### Therefore, the reference voltage level Vth can be adjusted by the resistances R1 and R3 as desired.

It should be noted that the gain Ga of the positive-phase amplifier depends on the resistance R2 while not depending on the resistance R3, and that the reference voltage level Vth depends on the resistance R3 while not depending on the resistance R2. This implies that the gain Ga of the positive-phase amplifier can be adjusted independently of the reference voltage level Vth.

### Second Embodiment

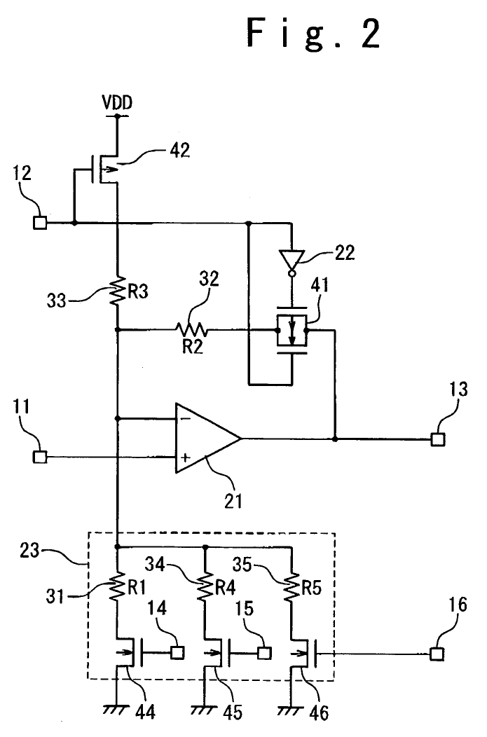

FIG. 2 is a circuit diagram illustrating the configuration of an input interface circuit according to a second embodiment of the present invention. The input interface circuit according to the second embodiment is provided with a differential amplifier 21, an inverter circuit 22, resistors 32 and 33, MOS switches 41 and 42 and a synthetic resistor circuit 23. It should be noted that the configuration of FIG. 2 is almost identical to that of FIG. 1, except for that the resistor 31 in FIG. 1 is replace with the synthetic resistor circuit 23. The synthetic resistor circuit 23 includes resistors 31, 34, 35 and MOS switches 44 to 46. In this embodiment, NMOS transistors are used as the MOS switches 44 to 46.

The signal input terminal 11 is connected with the non-inverting input (denoted by the symbol “+”) of the differential amplifier 21. The MOS switch 42, the resistor 33, and the synthetic resistor circuit 23 is serially connected between a power supply line VDD and a ground line GND. The control terminal (or the gate) of the MOS switch 42 is connected with an analog/digital select terminal 12. The connecting node of the resistor 33 and the synthetic resistor circuit 23 is connected with the inverting input (denoted by the symbol “−”) of the differential amplifier 21, and also connected with one end of the resistor 32. The output terminal of the differential amplifier 21 is connected with a signal output terminal 13, and also connected with the other end of the resistor 32. One of the control terminals of the MOS switch 41 is directly connected with the analog/digital select terminal 12, and the other is connected with the analog/digital select terminal 12 through the inverter circuit 22.

The inverter circuit 22 is used to drive the PMOS transistor of the MOS switch 41, and the MOS switch 41 is turned on and off in response to the voltage level on the analog/digital select terminal 12. Specifically, the MOS switch 41 is turned on when the analog/digital select terminal 12 is pulled up to the “H” level. When the analog/digital select terminal 12 is pulled down to the “L” level, on the other hand, the while the MOS switch 41 is turned off.

The control terminal of the MOS switch 42 is connected with the analog/digital select terminal 12, and the MOS switch 42 is turned on and off in response to the voltage level on the analog/digital select terminal 12. Specifically, the MOS switch 42 is turned off when the analog/digital select terminal 12 is pulled up to the “H” level. When the analog/digital select terminal 12 is pulled down to the “L” level, on the other hand, the while the MOS switch 41 is turned on. It should be noted that the MOS switches 41 and 42 performs complementary operations; when one of the MOS switches 41 and 42 is turned on, the other is turned off.

In this configuration, the resistor 32 is electrically connected between the output terminal 13 and the non-inverting input of the differential amplifier 21 to function as a feedback resistor, when the analog-digital select terminal 12 is pulled up to the “H” level. This allows the differential amplifier 21 to operate as a positive-phase amplifier that provides in-phase amplification for the input signal fed to the signal input terminal 11. When the analog/digital select terminal 12 is pulled down to the “L” level, on the other hand, the negative feedback loop is cut off, and the differential amplifier 21 operates as a comparator that compares the voltage levels on the inverting and non-inverting inputs thereof. In this case, the resistors 33 and 31 functions as a reference voltage level generator which generates a reference voltage level through voltage division of the power supply level vdd.

The synthetic resistor circuit 23 is configured so that the resistance thereof is controllable in response to voltage levels on control terminals 14 to 16. Specifically, the resistors 31, 34 and 35 are connected in parallel, and the MOS switches 44, 45 and 46 are connected in series between the ground line and the resistors 31, 34 and 35 and, respectively. The control terminals of the MOS switches 44, 45 and 46 are connected with the control terminals 14, 15 and 16, respectively. The MOS switches 44, 45 and 46 are turned on and off in response to the voltage levels on the control terminals 14, 15 and 16, respectively. This allows controlling the resultant resistance of the synthetic resistor circuit 23 by the voltage levels on the control terminals 14, 15 and 16.

For the case that the on-resistances of the MOS switches 44, 45 and 46 are sufficiently smaller than the resistance R1, R4 and R5 of the resistors 31, 34 and 35 respectively (this is usually the case in practice), the resultant resistance Z of the synthetic resistor circuit 23 is as follows:

Z=R1×R4×R5/(R1×R4+R4×R5+R5×R1), (3)

when all of the control terminals 14, 15 and 16 are pulled up to the “H” level to turn on the MOS switches 44, 45 and 46, for example.

When the control terminals 14 and 15 are pulled up to the “H” level with the control terminal 16 pulled down to the “L” level, on the other hand, the resultant resistance Z of the synthetic resistor circuit 23 is as follows:

Z=R1×R4/(R1+R4). (4)

### Those skilled in the art would appreciate that the resultant resistance Z of the synthetic resistor circuit 23 can be calculated for other combinations of the voltage levels on the control terminals 14, 15 and 16.

The signal input terminal 11 receives an analog input signal or a digital input signal, and the signal output terminal 13 outputs an analog output signal or a digital output signal, accordingly. For achieving analog amplification of the signal fed to the signal input terminal 11, the analog-digital select terminal 12 is pulled up to the “H” level. For digitizing the signal fed to the signal input terminal 11, on the other hand, the analog-digital select terminal 12 is pulled down to the “L” level.

The input interface circuit according to the second embodiment operates as follows: A description is first given of the analog amplification of the input signal fed to the signal input terminal 11. In this case, the analog-digital select terminal 12 is pulled up to the “H” level, and the MOS switch 42 is turned off, while the MOS switch 41 is turned on. As a result, the output of the differential amplifier 21 is connected with the inverting input of the differential amplifier 21 through the resistor 32, and also grounded through the synthetic resistor circuit 23. This allows the input interface circuit to operate as a positive-phase amplifier.

For the case that the on-resistance of the MOS switch 41 is sufficiently smaller than the resistance R2 of the resistor 32 (this is usually the case in practice), the gain Ga of the positive-phase amplifier is as follow:

Ga=1+R2/Z. (5)

It should be noted that the resultant resistance Z of the parallel resistance circuit 23 is dependent on the voltage levels on the control terminals 14 to 16. Therefore, the gain Ga can be adjusted by t the voltage levels on the control terminals 14 to 16 as desired.

For the signal digitalization of the input signal fed to the signal input terminal 11, on the other hand, the analog-digital select terminal 12 is pulled up to the “L” level. This results in that the MOS switch 42 is turned on, while the MOS switch 41 is turned off. In this case, the differential amplifier 21 operates as a comparator. The reference voltage level Vth fed to the non inverting input of differential amplifier 21, which is identical to the threshold level of the signal digitalization, is as follow:

Vth=Vdd×Z/(Z+R3). (6)

Since the resultant resistance Z of the parallel resistance circuit 23 is dependent on the voltage levels on the control terminals 14 to 16, the threshold level of the signal digitalization of the digital input signal can be adjusted by the voltage levels on the control terminals 14 to 16.

It should be noted that the configuration of the synthetic resistor circuit 23, in which the MOS switches 44, 45 and 46 are connected in series to the resistors 31, 34 and 35 in the configuration of FIG. 2, may be variously modified. In an alternative embodiment, the synthetic resistor circuit 23 may include an additional resistor directly connected with the ground line and the non-inverting input of the differential amplifier 21 in parallel to the resistors 31, 34 and 35. In another alternative embodiment, the resistors 31, 34, and 35 may be connected in series between the ground line and the non-inverting input of the differential amplifier 21, and the MOS switches 44, 45 and 46 are connected in parallel to the resistors 31, 34, and 35.

As thus described, the synthetic resistor circuit 23, which has a variable resistance, allows adjusting the gain of the analog amplification of the analog input signal and the threshold level of the signal digitization of the digital input signal.

### Third Embodiment

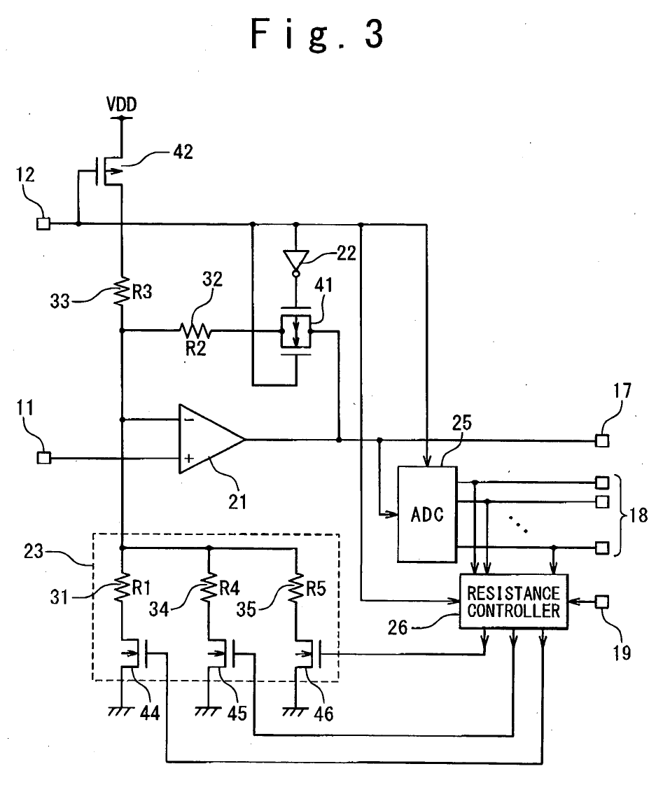

FIG. 3 is a circuit diagram illustrating the configuration of an input interface circuit according to the third embodiment of the present invention. The input interface circuit according to the third embodiment is configured to provide A/D conversion for the analog input signal to generate a corresponding digital signal, in addition to the gain-variable analog amplification. Semiconductor ICs are often required to handle analog input signals after converting the analog input signals into digital signals, and the configuration of the input interface circuit according to the third embodiment satisfies such requirement.

The input interface circuit according to the third embodiment is provided with a differential amplifier 21, an inverter circuit 22, resistors 32 and 33, MOS switches 41 and 42, a synthetic resistor circuit 23, an A/D converter 26 and a resistance controller 26. The synthetic resistor circuit 23 includes resistors 31, 34 and 35 and MOS switches 44 to 46. The configuration of the input interface circuit according to the third embodiment is almost similar to that of the input interface circuit according to the third embodiment, except for that the input interface circuit according to the third embodiment additionally include an A/D converter 25 and a resistance controller 26. Therefore, a description is only given of the A/D converter 25 and the resistance controller 26 in the following.

The input of the A/D converter 25 is connected with the output of the differential amplifier 21, and the outputs of the A/D converter 25 are connected with A/D converted signal outputs 18 and the inputs of the resistance controllers 26. The control terminal of the A/D converter 25 is connected with the analog/digital selection terminal 12. The outputs of the resistance controllers 26 are connected with the control terminals of the MOS switches 44 to 46, respectively. The resistance controller 26 is connected with the analog/digital selection terminal 12, and also connected with a resistor control signal input 19. The resistance controller 26 controls the voltage levels of the control terminals of the MOS switches 44 to 46 in response to the voltage levels on the analog/digital selection terminal 12 and the resistor control signal input 19.

The input interface circuit according to the third embodiment is configured to provide digital signals to the internal circuit of the semiconductor IC. When a digital input signal is fed to the signal input terminal 11, a corresponding digital output signal, which is generated through signal digitization by the differential amplifier 21, is output from a digital signal output terminal 17. When an analog input signal is fed to the signal input terminal 11, on the other hand, a set of digital output signals generated through A/D conversion by the A/D converter 25 are output from the A/D converted signal outputs 18. The digital output signals output from the A/D converted signal outputs 18 represent a digital value corresponding to the signal level of the analog input signal fed to the signal input terminal 11

The A/D converter 25 is activated when the analog/digital selection terminal 12 is pulled up to the “H” level. In other words, the A/D converter 25 provides A/D conversion for the output signal of the differential amplifier 21, and feeds the resultant digital signals to the A/D converted signal outputs 18, when the input interface circuit operates as an analog circuit. When the analog/digital selection terminal 12 is pulled down to the “L” level, on the other hand, the A/D converter 25 is deactivated and the outputs of the A/D converter 25 are disenabled.

The resistor controller 26 generates control signals for controlling the MOS switches 44 to 46 in response to the digital output signals received from the A/D converter 25 (which are also fed to the A/D converted signal outputs 18). The operation of the resistor controller 26 is controlled in response to the voltage level on the analog/digital select terminal 12.

When the analog/digital select terminal 12 is pulled up to the “H” level, the resistor controller 26 feeds the control signals to the MOS switches 44 to 46 in response to the digital output signals received from the A/D converter 25. Specifically, the resistor controller 26 latches the digital output signals received from the A/D converter 25 in response to the pull-up of the resistor control signal input 19, and generates the control signals fed to the MOS switches 44 to 46 in response to the digital output signals latched. When the signal level of the output of the differential amplifier 21 is too small and only a reduced number of the digital output signals received from the A/D converter 25 are effectively used to indicate the signal level of the output of the differential amplifier 21, the resistor controller 26 controls the MOS switches 44 to 46 so as to increase the gain Ga of the analog amplification, which is indicated by the formula (5); the gain Ga is increased by decreasing the resultant resistance Z of the synthetic resistor circuit 33. When the signal level of the output of the differential amplifier 21 is too large, causing overflow of the digital output signals generated by the A/D converter 25, the resistor controller 26 controls the MOS switches 44 to 46 to decrease the gain Ga, and thereby avoids the saturation of the A/D converter 25. Such operation achieves automatic gain control and effectively increases the dynamic range of the analog input signal.

In an alternative embodiment, the resistor controller 26 may control the MOS switches 44 to 46 in response to the time-average of the digital value output from the A/D converter 25. This allows the input interface circuit to operate as an AGC (automatic gain control) circuit, achieving normalization of the amplitude of the analog input signal. Instead, the resistor controller 26 may control MOS switches 44 to 46 in response to the change in the digital value received from the A/D converter 25. This allows gain control in response to the changing speed of the digital value output from the A/D converter 25.

When the analog/digital select terminal 12 is pulled down to the “L” level to achieve signal digitization, the A/D converter 25 is deactivated; the output terminals of the A/D converter 25 are set to high-impedance. In this case, the A/D converted signal outputs 18 are used as input terminals used to feed control signals to the resistance controller 26 for controlling the resultant resistance Z of the synthetic resistor circuit 23. The control signals are fed to the A/D converted signal outputs 18 from an internal circuit (such as a CPU and a threshold setting register). The resistance controller 26 controls the MOS switches 44 to 46 to adjust the threshold level of the signal digitization in response to the control signals fed to the A/D converted signal outputs 18.

The control pattern of the MOS switches 44 to 46 for adjustment of the threshold level Vth may be different from that for the gain control of the analog amplification.

In one embodiment, the resistor controller 26 may include a storage device, such as a semiconductor memory, storing a database table describing the association of the pattern of the control signals fed to the resistor controller 26 with the pattern of the control signals 55 to 57 fed to the MOS switches 44 to 46. The database table is used for converting the control signals received from the A/D converted signal outputs 18 into the resistor controller 26 in to the control signals 55 to 57. In an alternative embodiment, the resistor controller 26 may include a logic circuit or firmware (or a software program) for converting the signals received from the output signals of A/D converter 25 or the A/D converted signal outputs 18 into the resistor controller 26. In another alternative embodiment, the MOS switches 44 to 46 may be controlled in response to only the voltage levels on the analog/digital select terminal 12 and the resistance control signal input 19, in the adjustment of the threshold level Vth.

As thus described, the input interface circuit according to the third embodiment is provided with the A/D converter 25 and the resistor controller 26, and thereby achieves sophisticated control including automatic gain control in addition to the external adjustment of the threshold level and the gain.

### Fourth Embodiment

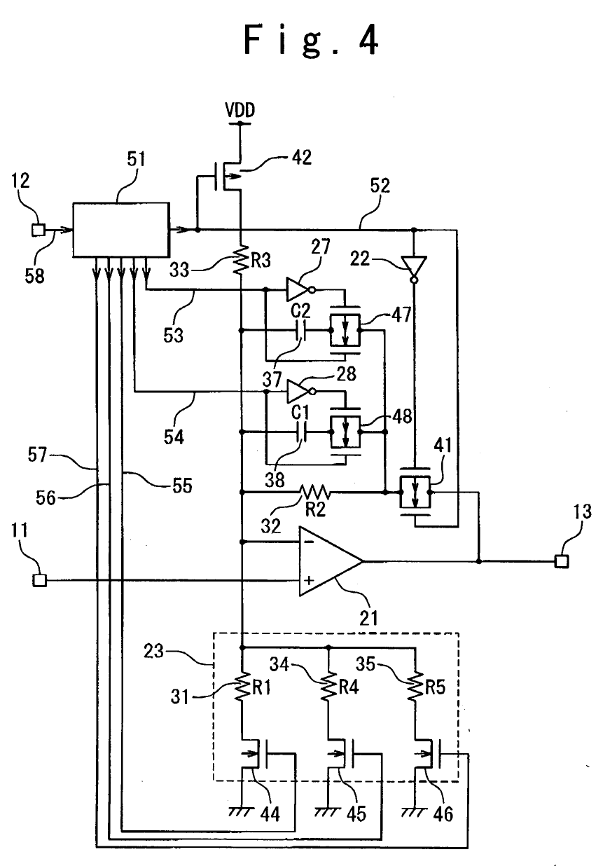

FIG. 4 is a circuit diagram illustrating the configuration of an input interface circuit according to a fourth embodiment of the present invention. The input interface circuit according to the fourth embodiment is configured to achieve analog signal filtering with a variable cut-off frequency.

Specifically, the input interface circuit according to the fourth embodiment is provided with a differential amplifier 21, inverter circuits 22, 27 and 28, resistors 32 and 33, capacitors 37 and 38, MOS switches 41, 42, 47 and 48, a synthetic resistor circuit 23 and a MOS switch controller 51. The synthetic resistor circuit 23 includes resistors 31, 34 and 35, and MOS switches 44 to 46.

A signal input terminal 11 is connected with the non-inverting input (denoted by the symbol “+”) of the differential amplifier 21. The MOS switch 42, the resistor 33, and the synthetic resistor circuit 23 is serially connected between a power supply line VDD and a ground line GND. The control terminal (or the gate) of the MOS switch 42 is connected with the MOS switch controller 51. The connecting node of the resistor 33 and the synthetic resistor circuit 23 is connected with the inverting input (denoted by the symbol “−”) of the differential amplifier 21, and also connected with the resistor 32 and the capacitors 37 and 38. The output terminal of the differential amplifier 21 is connected with a signal output terminal 13, and also connected with the other end of the resistor 32. The connecting node of the MOS switch 41 and the resistor 32 is connected with the capacitors 37 and 38 through the MOS switches 47 and 48, respectively.

One of the control terminals of the MOS switch 41 is directly connected with the MOS switch controller 51, and the other is connected with the MOS switch controller 51 through the inverter circuit 22. The control terminal of the MOS switch 42 is also connected with the MOS switch controller 51 commonly with the other of the control terminals of the MOS switch 41. Therefore, the MOS switches 41 and 42 are turned on and off in response to an output signal 51 generated by the MOS switch controller 51. Specifically, the MOS switch 42 is turned off and the MOS switch 41 is turned on, when the control signal 52 is pulled up to the “H” level. When the control signal 52 is pulled down to the “L” level, on the other hand, the MOS switch 42 is turned on and the MOS switch 41 is turned off.

One of the control terminals of the MOS switch 47 is directly connected with the MOS switch controller 51, and the other is connected with the MOS switch controller 51 through the inverter circuit 27. The MOS switch 47 is turned on and off in response to a control signal 53 generated by the MOS switch controller 51. When the control signal 53 is pulled up to the “H” level, the MOS switch 47 is turned on to allow the capacitor 37, which has a capacitance of C2, to be electrically connected in parallel to the resistor 32.

Correspondingly, one of the control terminals of the MOS switch 48 is directly connected with the MOS switch controller 51, and the other is connected with the MOS switch controller 51 through the inverter circuit 28. The MOS switch 48 is turned on and off in response to another control signal 54 generated by the MOS switch controller 51. When the control signal 54 is pulled up to the “H” level, the MOS switch 48 is turned on to allow the capacitor 38, which has a capacitance of C1, to be electrically connected in parallel to the resistor 32.

The synthetic resistor circuit 23 is configured to have a variable resistance controlled by the MOS switch controller 51 Specifically, the resistors 31, 34 and 35 are connected in parallel, and the MOS switches 44, 45 and 46 are connected in series between the ground line and the resistors 31, 34 and 35 and, respectively. The control terminals of the MOS switches 44, 45 and 46 are connected with the MOS switch controller 51. The MOS switches 44, 45 and 46 are turned on and off in response to control signals 55, 56 and 57 received from the switch controller 51, respectively. In the following description, it is assumed that the resistances of the resistors 31, 34 and 35 are R1, R4 and R5, respectively, the on-resistances of the MOS switches 44 to 46 are sufficiently small compared with the resistances R1, R4, R5 of the resistors 31, 34 and 35. The resultant resistance Z of the synthetic resistor circuit 23 is obtained as the parallel connection resistance of selected ones of the resistors 31, 34 and 35, as described in the second embodiment.

The MOS switch controller 51 is connected with the analog/digital select terminal 12 to receive an input mode switch signal 58. The outputs of the MOS switch controller 51 are connected with the MOS switches 41, 42, 44, 45, 46, 47, 48. The MOS switch controller 51 feeds the control signals 52 to 57 to the associated MOS switches in response to the input mode switch signal 58. In this embodiment, the input mode switch signal 58 is fed through a single signal line from the analog/digital select terminal 12 as an encoded pulse signal. The MOS switch controller 51 controls the signal levels of the control signals 52 to 57 in response to the number of pulses and pulse widths of the respective pulses within the input mode switch signal 58.

The input interface circuit according to the fourth embodiment operates as follows: For providing signal digitization for the input signal fed to the signal input terminal 11, the MOS switch controller 51 pulls down the control signal 52 to the “L” level. This allows the MOS switch 42 to be turned on, and the MOS switch 41 to be turned off. The operation of the input interface circuit in implementing the signal digitization is identical to that in the second embodiment, except for that the MOS switches 44 to 46 are controlled by the MOS switch controller 51.

For providing analog amplification and filtering, on the other hand, the MOS switch controller 51 pulls up the control signal 52 to the “H” level. This allows the MOS switch 42 to be turned off, and the MOS switch 41 to be turned on. When both of the control signals 53 and 54 are pulled down to the “L” level by the MOS switch controller 51, the MOS switched 47 and 48 are turned off, allowing the input interface circuit to operate as a positive-phase amplifier, as is the case of the second embodiment. The gain Ga of the positive-phase amplifier is as follows:

Ga=1+R2/Z, (7)

where Z is the resultant resistance of the synthetic resistor circuit 23.

When the control signal 54 is pulled up to the “H” level, the MOS switch 48 is turned on, incorporating the capacitor 38 into the feedback loop of the differential amplifier 21 in parallel to the resistor 32. This allows the input interface circuit according to the fourth embodiment to operate as a low pass filter. The cut-off frequency f1 is as follows:

f1=1/(2π×C1×R2), (8)

where R2 is the resistance of the resistor 32, and C1 is the capacitance of the capacitor 38.

When the control signal 53 is additionally pulled up to the “H” level, the MOS switch 47 is turned on, additionally incorporating the capacitor 37 into the feedback loop of the differential amplifier 21 in parallel to the resistor 32. In this case, the cut-off frequency f2 is as follows:

f2=1/(2π×(C1+C2)×R2), (8)

### As thus described, the cut-off frequency of the analog filtering is programmable by the combination of the states of the MOS switches 47 and 48.

The low pass filtering described above is preferably used as pre-filtering for an A/D converter.

Although the MOS switches 47 and 48 are each connected in series to the MOS switch 41 in this embodiment, the configuration of the feedback loop from the output of the differential amplifier 21 to the input thereof may be modified. For example, the MOS switches 41, 47 and 48 may be connected in parallel. In this case, the control logic of the MOS switch controller 51 is modified accordingly. Additionally, the feedback loop may additionally include resistors connected in series to the capacitors 37 and 38, respectively, to adjust not only the cut-off frequency but also the gain. The feedback loop may be modified so that the input interface circuit provides high-pass filtering or band-pass filtering.

In summary, the input interface circuits described in the above embodiments allows using the signal input terminal for both of digital and analog signal inputs, and thereby reduces the number of interface terminals. Additionally, the input interface circuits described in the above embodiments allows adjusting the gain of the analog signal input and the threshold level of the signal digitization for the digital signal input, independently.

It is apparent that the present invention is not limited to the above embodiments, but may be modified and changed without departing from the scope of the invention.

For example, although the synthetic resistor circuit 23 is described as including resistors 31, 34 and 35 and MOS switches 44, 45 and 46 in the above-described embodiments, the synthetic resistor circuit 23 may additionally include a resistor(s) and MOS switch(es). Each MOS switch may be selected from a PMOS transistor, an NMOS transistor, and a transfer gate depending on the use conditions.

What is claimed is:

1. An input interface circuit comprising:
a reference voltage level generator generating a reference voltage level;
a differential amplifier having a non-inverting input receiving an input signal and an inverting input receiving said reference voltage level; and
a feedback circuit for achieving feedback of said output signal of said differential amplifier to said inverting input,
wherein said feedback circuit includes a switch for allowing and prohibiting said feedback of said output signal.

2. The input interface circuit according to claim 1, wherein said switch is turned off to prohibit said feedback of said output signal when said input signal is a digital signal, and
wherein said switch is turned on to allow said feedback of said output signal when said input signal is an analog signal.

3. The input interface circuit according to claim 1 wherein said feedback circuit further includes a feedback resistor for achieving said feedback of said output signal therethrough, and
wherein said switch is turned off to prohibit said feedback of said output signal through said feedback resistor, when said input signal is a digital signal.

4. The input interface circuit according to claim 1, wherein said reference level generator includes:
a bias switch; and
a bias resistor,
wherein said bias switch and said bias resistor are serially connected between a first power line and a node connected with said inverting input, and
wherein said bias switch is turned off when said input signal is an analog signal.

5. The input interface circuit according to claim 1, wherein said reference level generator includes:
a resistor circuit connected between a second power line and a node connected with said inverting input.

6. The input interface circuit according to claim 5, wherein said resistor circuit has a variable resistance.

7. The input interface circuit according to claim 5, wherein said resistor circuit comprises:
a plurality of resistors connected in parallel; and
a plurality of switches connected in series to said plurality of resistors, respectively,
wherein said plurality of switches are turned on and off in response to control signals, respectively.

8. The input interface circuit according to claim 5, wherein said resistor circuit comprises:
a plurality of resistors connected in series; and
a plurality of switches connected in parallel to said plurality of resistors, respectively,
wherein said plurality of switches are turned on and off in response to control signals, respectively.

9. The input interface circuit according to claim 6, further comprising:
an A/D converter performing A/D conversion on said output signal; and
a resistor controller generating said control signals in response to an output of said A/D converter.

10. The input interface circuit according to claim 9, wherein said resistor controller generates said control signals in response to a change in a digital value output from said A/D converter.

11. The input interface circuit according to claim 9, wherein said resistor controller generates said control signals so that a signal level of said output signal of said differential amplifier is in a predetermined range.

12. The input interface circuit according to claim 9, wherein said resistor controller generates said control signals in response to a time-average of a digital value output from said A/D converter.

13. The input interface circuit according to claim 1, wherein said feedback circuit includes a capacitor element to provide filtering when said switch is turned on.

14. The input interface circuit according to claim 13, wherein said capacitor element includes a capacitance-adjustment switch for controlling the capacitance of said capacitor element, and
wherein a cut-off frequency of said filtering is controlled by turn-on and off of said capacitance-adjustment switch.

15. The input interface circuit according to claim 13, wherein the capacitor element includes;
a plurality of capacitors connected in parallel, and
a plurality of switches connected in series to said plurality of capacitors, respectively, and
wherein said a cut-off frequency of said filtering is controlled by turn-on and off of said plurality of switches.

16. An input interface circuit comprising:
a bias switch;
a bias resistor, wherein said bias switch and said bias resistor are connected in series between a first power line and a connecting node;
a resistor circuit connected between said connecting node and a second power line;
a differential amplifier having an inverting input connected with said connecting node, and a non-inverting input receiving an input signal;
a feedback resistor; and
a feedback switch,
wherein said feedback resistor and said feedback switch are connected in series between an output terminal of said differential amplifier and said inverting input, and
wherein said bias switch and said feedback switch perform complementary operations each other, in response to a select signal.

17. The input interface circuit according to claim 16, wherein said resistor circuit includes:
a plurality of resistors connected in parallel; and
a plurality of switches connected in series to said plurality of resistors, respectively.

18. The input interface circuit according to claim 16, wherein said resistor circuit includes;
a plurality of resistors connected in series; and
a plurality of switches connected in parallel to said plurality of resistors, respectively.

19. A semiconductor integrated circuit comprising said input interface circuit according to claim 1.

20. A semiconductor integrated circuit comprising said input interface circuit according to claim 16.
